(19) United States
(12) Patent Application Publication
(10) Pub. No.: US 2024/0381635 A1
(43) Pub. Date: Nov. 14, 2024

(54) MEMORY DEVICE AND METHOD OF MANUFACTURING THE MEMORY DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/485,808

(22) Filed: Oct. 12, 2023

(30) Foreign Application Priority Data
May 9, 2023 (KR) 10-2023-0059666

(51) Int. Cl. H10B 41/35

(52) U.S. Cl. CPC H10B 41/35; H10B 41/27

(57) ABSTRACT

The present technology includes a memory device and a method of manufacturing the memory device. The memory device includes source contacts passing through a stack structure stacked on a source line, first supports passing through the stack structure between the source contacts, second supports passing through the stack structure between the first supports and the source contacts, and an auxiliary pattern passing through a portion of the stack structure between the first supports. The source contacts, and the first and second supports contact the source line, and the auxiliary pattern is spaced apart from the source line.

### CROSS-REFERENCE TO RELATED APPLICATION

The present application claims priority under 35 U.S.C. § 119 (a) to Korean patent application number 10-2023-0059666 filed on May 9, 2023, in the Korean Intellectual Property Office, the entire disclosure of which is incorporated by reference herein.

### BACKGROUND

### 1. Technical Field

Embodiments of the present disclosure generally relate to a memory device and a method of manufacturing the memory device, and more particularly, to a memory device including a support and a method of manufacturing the memory device including the support.

### 2. Related Art

A memory device may include a memory cell array in which data is stored, peripheral circuits configured to perform a program, read, or erase operation of the memory cell array, and a control circuit configured to control the peripheral circuits.

The memory cell array may include a plurality of memory blocks. When the memory blocks are formed in a three-dimensional structure, the memory blocks may be separated from each other by slit regions.

The memory blocks formed in the three-dimensional structure may include a stack structure stacked from a substrate in a vertical direction. The stack structure may include a plurality of gate lines and insulating layers that are alternately stacked. Sacrificial layers and insulating layers may be stacked in a portion of the stack structure. When the memory blocks are formed as the stack structure, supports may be used to prevent or mitigate the stack structure from bending or collapsing during a manufacturing process of the memory device. The supports may be positioned at both ends of the stack structure or may be positioned between the memory blocks.

As an integration degree of the memory device increases, a size of the supports may also decrease, and thus a void may occur in the supports. When a volume of the void increases, a function as the support may deteriorate, and thus the volume of the void is required to be reduced.

### SUMMARY

According to an embodiment of the present disclosure, a memory device includes source contacts passing through a stack structure stacked on a source line, first supports passing through the stack structure between the source contacts, second supports passing through the stack structure between the first supports and the source contacts, and an auxiliary pattern passing through a portion of the stack structure between the first supports. The source contacts, and the first and second supports contact the source line, and the auxiliary pattern is spaced apart from the source line.

According to an embodiment of the present disclosure, a memory device includes first supports extending along a first direction and arranged parallel to each other; auxiliary patterns spaced apart from each other along the first direction, the auxiliary patterns located between the first supports; and voids spaced apart from each other along the first direction, the voids located inside the first supports.

According to an embodiment of the present disclosure, a method of manufacturing a memory device includes forming first holes exposing a source line by passing through a stack structure positioned on the source line and spaced apart from each other in a first direction, forming trenches exposing the source line by passing through the stack structure in a region spaced apart from the first holes in a second direction and having a line shape extending in the first direction, forming second holes exposing a portion of the stack structure by passing through the portion of the stack structure between the trenches and spaced apart from each other in the first direction, filling the first holes, the trenches, and the second holes with an insulating material, and performing a heat treatment process for filling a portion of a void in the trenches.

### BRIEF DESCRIPTION OF THE DRAWINGS

FIG. 1 is a diagram illustrating a memory device.

FIG. 2 is a diagram illustrating a memory cell array.

FIGS. 3A, 3B, and 3C are diagrams illustrating a memory device which does not include an auxiliary pattern.

FIGS. 4A, 4B, 4C, and 4D are diagrams illustrating a memory device including an auxiliary pattern according to an embodiment of the present disclosure.

FIGS. 5A, 5B, and 5C are layouts illustrating a method of manufacturing a memory device according to an embodiment of the present disclosure.

FIGS. 6A, 6B, and 6C are cross-sectional views illustrating a method of manufacturing a memory device according to an embodiment of the present disclosure.

FIGS. 7A, 7B, and 7C are cross-sectional views illustrating a method of manufacturing a memory device according to an embodiment of the present disclosure.

FIG. 8 is a diagram illustrating a memory card system to which a memory device of the present disclosure is applied.

FIG. 9 is a diagram illustrating a solid state drive (SSD) system to which a memory device of the present disclosure is applied.

### DETAILED DESCRIPTION

Specific structural or functional descriptions disclosed below are exemplified to describe embodiments according to the concepts of the present disclosure. The embodiments according to the concepts of the present disclosure are not construed as being limited to the embodiments described below, and may be variously modified and replaced with other equivalent embodiments.

Hereinafter, terms such as first and second may be used to describe various components, but the components are not limited by the terms. The terms are used for the purpose of distinguishing one component from another component. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

An embodiment of the present disclosure provides a memory device capable of reducing a defect of the memory device and a method of manufacturing the same. According to an embodiment of the present disclosure, a memory device includes first supports extending along a first direction and arranged parallel to each other, auxiliary patterns spaced apart from each other along the first direction between the first supports, and voids spaced apart from each other along the first direction inside the first supports. An embodiment of the present technology may increase yield by reducing a defect that may occur during a manufacturing process of a memory device.

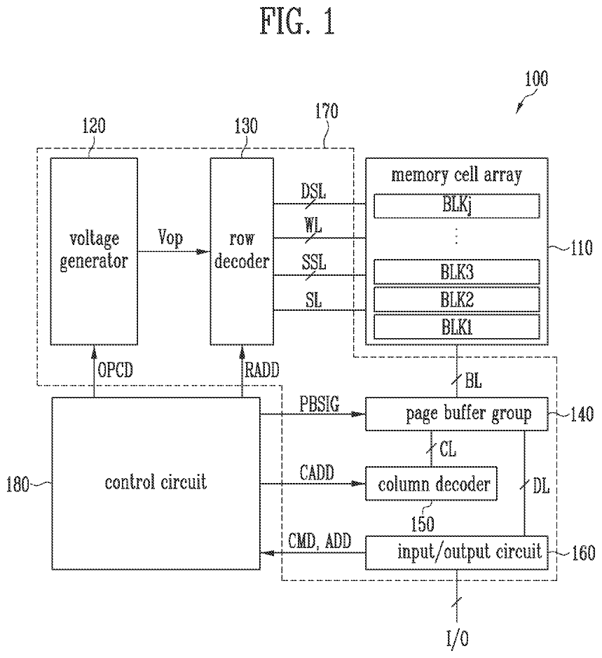

FIG. 1 is a diagram illustrating a memory device.

Referring to FIG. 1, the memory device 100 may include a memory cell array 110, a peripheral circuit 170, and a control circuit 180.

The memory cell array 110 may include first to j-th memory blocks BLK1 to BLKj. Each of the first to j-th memory blocks BLK1 to BLKj may include memory cells capable of storing data. The memory blocks may be formed in a three-dimensional structure. Drain select lines DSL, word lines WL, source select lines SSL, and a source line SL may be connected to each of the first to j-th memory blocks BLK1 to BLKj, and a bit line BL may be commonly connected to the first to j-th memory blocks BLK1 to BLKj.

The first to j-th memory blocks BLK1 to BLKj may be formed in a two-dimensional structure or a three-dimensional structure. The memory blocks having the two-dimensional structure may include memory cells arranged parallel to a substrate. The memory blocks having a three-dimensional structure may include memory cells stacked on a substrate in a vertical direction. The first to j-th memory blocks BLK1 to BLKj of the present embodiment are formed in a three-dimensional structure.

The memory cells may store 1 bit or 2 bits or more of data according to a program method. For example, a method in which 1 bit of data is stored in one memory cell is referred to as a single level cell method, and a method in which 2 bits of data is stored in one memory cell is referred to as a multi-level cell method. A method in which 3 bits of data is stored in one memory cell is referred to as a triple level cell method, and a method in which 4 bits of data is stored in one memory cell is referred to as a quad level cell method. In addition to this, five bits or more of data may be stored in one memory cell.

The peripheral circuit 170 may be configured to perform a program operation of storing data in the memory cell array 110, a read operation of outputting the data stored in the memory cell array 110, and an erase operation of erasing the data stored in the memory cell array 110. For example, the peripheral circuit 170 may include a voltage generator 120, a row decoder 130, a page buffer group 140, a column decoder 150, and an input/output circuit 160.

The voltage generator 120 may generate various operation voltages Vop used for the program operation, the read operation, or the erase operation in response to an operation code OPCD. For example, the voltage generator 120 may be configured to generate program voltages, turn on voltages, turn off voltages, negative voltages, precharge voltages, verify voltages, read voltages, pass voltages, or erase voltages in response to the operation code OPCD. The operation voltages Vop generated by the voltage generator 120 may be applied to the drain select lines DSL, the word lines WL, the source select lines SSL, and the source line SL of memory block selected through the row decoder 130.

The program voltages may be voltages applied to a selected word line among the word lines WL during the program operation, and may be used to increase a threshold voltage of memory cells connected to the selected word line. The turn on voltages may be applied to the drain select lines DSL or the source select lines SSL, and may be used to turn on drain select transistors or source select transistors. The turn off voltages may be applied to the drain select lines DSL or the source select lines SSL, and may be used to turn off the drain select transistors or the source select transistors. For example, the turn off voltage may be set to 0V. The precharge voltages may be a voltage higher than 0V, and may be applied to bit lines during the read operation. The verify voltages may be used during a verify operation for determining whether a threshold voltage of selected memory cells is increased to a target level. The verify voltages may be set to various levels according to the target level and may be applied to the selected word line.

The read voltages may be applied to the selected word line during the read operation of the selected memory cells. For example, the read voltages may be set to various levels according to a program method of the selected memory cells. The pass voltages may be voltages applied to unselected word lines among the word lines WL during the program or read operation, and may be used to turn on memory cells connected to the unselected word lines.

The erase voltages may be used during the erase operation for erasing the memory cells included in the selected memory block, and may be applied to the source line SL.

The row decoder 130 may be configured to transmit the operation voltages Vop to the drain select lines DSL, the word lines WL, the source select lines SSL, and the source line SL connected to the selected memory block according to a row address RADD. For example, the row decoder 130 may be connected to the voltage generator 120 through global lines, and may be connected to the first to j-th memory blocks BLK1 to BLKj through the drain select lines DSL, the word lines WL, the source select lines SSL, and the source line SL.

The page buffer group 140 may include page buffers (not shown) respectively connected to the first to j-th memory blocks BLK1 to BLKj. Each of the page buffers (not shown) may be connected to the first to j-th memory blocks BLK1 to BLKj through the bit lines BL. During the read operation, the page buffers (not shown) may sense a current or a voltage of the bit lines that vary according to threshold voltages of the selected memory cells, and temporarily store the sensed data, in response to page buffer control signals PBSIG.

The column decoder 150 may be configured so that data is transmitted between the page buffer group 140 and the input/output circuit 160 in response to a column address CADD. For example, the column decoder 150 may be connected to the page buffer group 140 through column lines CL and may transmit enable signals through the column lines CL. The page buffers (not shown) included in the page buffer group 140 may receive or output the data through data lines DL in response to the enable signals.

The input/output circuit 160 may be configured to receive or output a command CMD, an address ADD, or data through input/output lines I/O. For example, the input/output circuit 160 may transmit the command CMD and the address ADD received from an external controller to the control circuit 180 through the input/output lines I/O, and transmit the data received from the external controller to the page buffer group 140 through the input/output lines I/O. Alternatively, the input/output circuit 160 may output the data received from the page buffer group 140 to the external controller through the input/output lines I/O.

The control circuit 180 may output the operation code OPCD, the row address RADD, the page buffer control signals PBSIG, and the column address CADD in response to the command CMD and the address ADD. For example, when the command CMD input to the control circuit 180 is a command corresponding to the program operation, the control circuit 180 may control the peripheral circuits 170 to perform the program operation of the memory block selected by the address ADD. When the command CMD input to the control circuit 180 is a command corresponding to the read operation, the control circuit 180 may control the peripheral circuits 170 to perform the read operation of the memory block selected by the address and output the read data. When the command CMD input to the control circuit 180 is a command corresponding to the erase operation, the control circuit 180 may control the peripheral circuits 170 to perform the erase operation of the selected memory block.

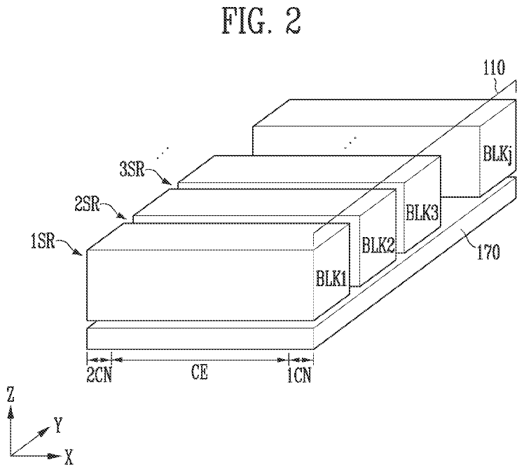

FIG. 2 is a diagram illustrating the memory cell array.

Referring to FIG. 2, the memory cell array 110 may be positioned on the peripheral circuits 170, but a position of the memory cell array 110 and the peripheral circuit is not limited to a position shown in FIG. 2. For example, the memory cell array 110 may be positioned on the same plane as the peripheral circuits 170 or may be formed on different substrates and then come into contact with each other.

The memory cell array 110 may include the first to j-th memory blocks BLK1 to BLKj. The first to j-th memory blocks BLK1 to BLKj may be spaced apart from each other along a Y direction. The first to j-th memory blocks BLK1 to BLKj may be configured identically to each other, and may be separated from each other by slit regions 1SR, 2SR, 3SR, and . . . Each of the slit regions 1SR, 2SR, 3SR, and . . . may extend along an X direction. For example, the first memory block BLK1 may be positioned between the first and second slit regions 1SR and 2SR, and the second memory block BLK2 may be positioned between the second and third slit regions 2SR and 3SR.

Each of the first to j-th memory blocks BLK1 to BLKj may be divided into a cell region CE and first and second connection regions 1CN and 2CN. The cell region CE may be positioned between the first and second connection regions 1CN and 2CN. Cell plugs including memory cells may be included in the cell region CE. At least one of the first and second connection regions 1CN and 2CN may include lines and contacts for electrically connecting gate lines connected to the cell plugs to the peripheral circuits 170. In addition, at least one of the first and second connection regions 1CN and 2CN may include supports for supporting a stack structure configuring the memory block.

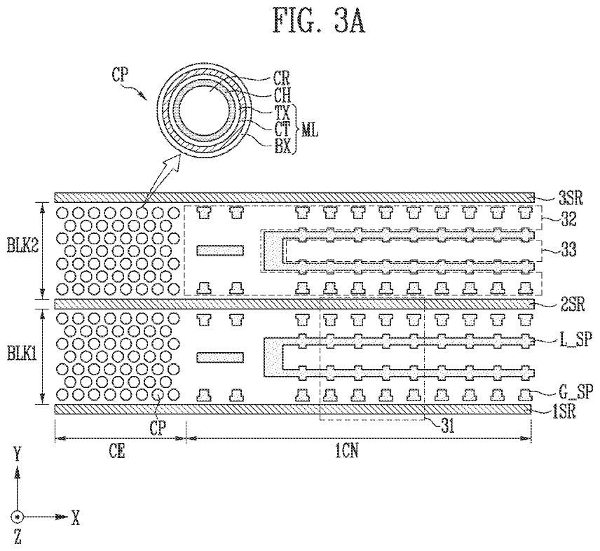

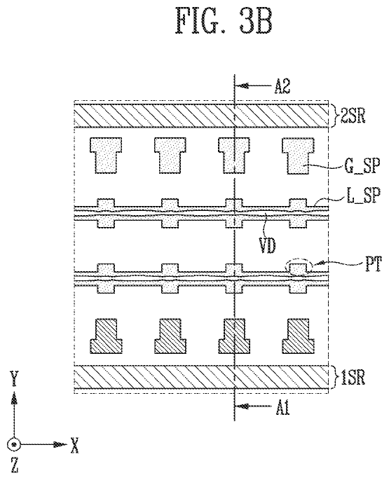

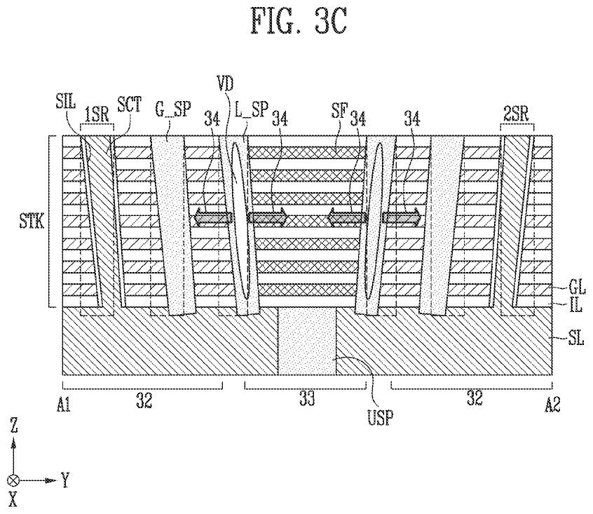

FIGS. 3A to 3C are diagrams illustrating a memory device which does not include an auxiliary pattern.

FIG. 3A is a layout of the memory device, FIG. 3B is an enlarged layout of a portion 31 of FIG. 3A, and FIG. 3C is a cross-sectional view of a structure of FIG. 3B taken in a direction A1-A2.

Referring to FIG. 3A, the first and second memory blocks BLK1 and BLK2 among the first to j-th memory blocks BLK1 to BLKj shown in FIG. 2 are shown.

Each of the first and second memory blocks BLK1 and BLK2 may be separated from each other by the slit regions. For example, the first and second memory blocks BLK1 and BLK2 may be separated from each other by a second slit region 2SR. A source contact or an insulating material may be formed inside the first to third slit regions 1SR to 3SR.

The first and second memory blocks BLK1 and BLK2 may include the cell region CE and the first connection region 1CN. The cell plugs CP including the memory cells may be included in the cell region CE, and first supports L_SP and second supports G_SP for supporting the memory blocks may be included in the first connection region 1CN. Although not shown in the drawings, the lines and the contacts electrically connecting the gate lines of the memory block and the peripheral circuits to each other may be further included in the first connection region 1CN.

The cell plug CP may include memory cells and select transistors. For example, the cell plugs CP corresponding to the memory cells or the select transistors may include a core pillar CR, a channel layer CH, and a memory layer ML. The memory layer ML may include a tunnel isolation layer TX, a charge trap layer CT, and a blocking layer BX. The core pillar CR may have a cylindrical shape and may be formed of an insulating material or a conductive material. The channel layer CH may have a cylindrical shape surrounding a side surface of the core pillar CR, and may be formed of polysilicon. The tunnel insulating layer TX may have a cylindrical shape surrounding a side surface of the channel layer CH and may be formed of an oxide layer. The charge trap layer CT may have a cylindrical shape surrounding a side surface of the tunnel insulating layer TX and may be formed of a nitride layer. The blocking layer BX may have a cylindrical shape surrounding a side surface of the charge trap layer CT and may be formed of an oxide layer.

Referring to FIGS. 3A and 3B, the first supports L_SP may be formed in a line shape to distinguish a region 32 where the gate lines extend from a region 33 where sacrificial layers extend in the first connection region 1CN, and may have a layout that surrounds a region where the sacrificial layers are formed. The first supports L_SP may be formed of an insulating material. In an embodiment, the first supports L_SP may include protrusions PT to support the stack structure configuring the memory block and fill a trench with an insulating material. In an embodiment, the first supports L_SP may include protrusions PT to support the stack structure configuring the memory block and to facilitate filling a trench with an insulating material. The second supports G_SP may also have a concavo-convex structure. In an embodiment, the second supports G_SP may also have a concavo-convex structure to facilitate supporting stacked gate lines. The second supports G_SP may also be formed of an insulating material.

The first supports L_SP may extend in a first direction X, and the second supports G_SP may be spaced apart from each other in the first direction X. The first supports L_SP may be spaced apart from each other and arranged in parallel along a second direction Y perpendicular to the first direction X. Since the first supports L_SP have the line shape, a void VD may occur in a partial region due to a characteristic of a manufacturing process. The void VD refers to a space in which the insulating material configuring the first supports L_SP is not completely filled in the trench. Even though the protrusions PT are included in the first supports L_SP, a size of the first supports L_SP may decrease as an integration degree of the memory device increases. Therefore, the void VD may be formed along a direction in which the first supports L_SP extend. For example, when the first supports L_SP extend along the first direction X, the void VD may also extend along the first direction X.

Referring to FIGS. 3B and 3C, when the void VD is formed in the first supports L_SP, a volume of the void VD may increase in a process performed at a high temperature such as a heat treatment step (34). Accordingly, some structures supporting a stack structure STK may be bent or inclined. The stack structure STK may be positioned on the source line SL. The source line SL may be formed of a conductive material through which a current may flow. The stack structure STK may include insulating layers IL, gate lines GL, and sacrificial layers SF stacked on the source line SL in a third direction Z. The first and second slit regions 1SR and 2SR may be regions for dividing the memory blocks, and sidewall insulating layers SIL and a source contact SCT may be formed inside each of the first and second slit regions 1SR and 2SR. The sidewall insulating layers SIL may be formed on sidewalls of each of the first and second slit regions 1SR and 2SR, and the source contact SCT may be formed between the sidewall insulating layers SIL and may contact the source line SL. The first support L_SP and the second support G_SP may be formed to support the stack structure STK during the manufacturing process of the memory device. In an embodiment, the first support L_SP and the second support G_SP may pass through the stack structure STK.

The sacrificial layers SF included in the stack structure STK may be positioned on the same layer as the gate lines GL and may be positioned between regions 32 where the gate lines GL are positioned. For example, the insulating layers IL and the gate lines GL may be alternately stacked on the source line SL in the regions 32 where the gate lines GL are positioned, and the insulating layers IL and the sacrificial layers SF may be alternately stacked on the source line SL in the region 33 where the sacrificial layers SF are positioned. The insulating layers IL may be formed of an oxide layer, and the sacrificial layers SF may be formed of a nitride layer. The gate lines GL may be formed of a metal material such as tungsten (W), molybdenum (Mo), cobalt (Co), and nickel (Ni), or a semiconductor material such as silicon (Si) or poly-silicon (Poly-Si). The source contact SCT may be positioned in the first and second slit regions 1SR and 2SR and may be formed of a conductive material. Since the source contact SCT is formed of the conductive material, a sidewall insulating layer SIL for electrically blocking the source contact SCT and the gate lines GL may be formed of an oxide layer.

A lower support USP may be further formed in a portion of a region where the source line SL is formed. The lower support USP may have a layout of a cylinder or line shape. The lower support USP may be formed to support the stack structure STK during a process of forming the source line SL. The lower support USP may be formed of an insulating material. The lower support USP may be positioned below the region 33 where the sacrificial layers SF are formed. The first support L_SP may be positioned between the sacrificial layers SF and the gate lines GL, and the second support G_SP may be positioned between the first support L_SP and the first or second slit region 1SR or 2SR. The first and second supports L_SP and G_SP may be formed of an insulating material.

When the void VD is formed in the first supports L_SP, the void VD may be surrounded by the insulating material configuring the first supports L_SP. The void VD may be an air gap.

When the heat treatment process is performed after the void VD is formed, the volume of the void VD may increase due to high temperature. When the volume of the void VD increases, stresses 34 may be applied to the stack structure STK, and some structures included in the stack structure STK may be bent or inclined due to the stresses 34. In FIG. 3C, the first support L_SP, the second support G_SP, the source contact SCT, and the sidewall insulating layer SIL are shown to be inclined in directions symmetrical to each other with respect to a region where the lower support USP is formed, a direction in which the stack structure STK is bent or inclined may vary according to a position where the void VD is formed.

As described above, when a portion of the stack structure STK is bent or inclined, a defect such as disconnection between structures which are required to be electrically connected to each other or connection between structures which are required to be electrically blocked from each other may occur in a partial region of the stack structure STK.

In an embodiment described below, a memory device and a method of manufacturing the memory device capable of reducing a size or a length of the void VD that may be formed in the first support L_SP are disclosed.

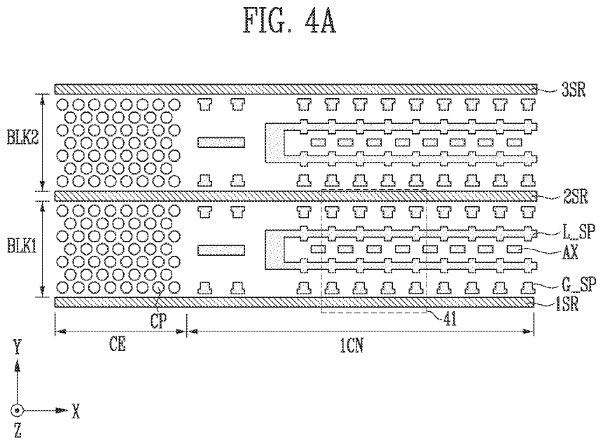

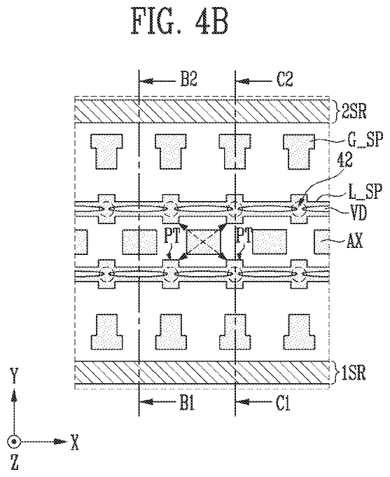

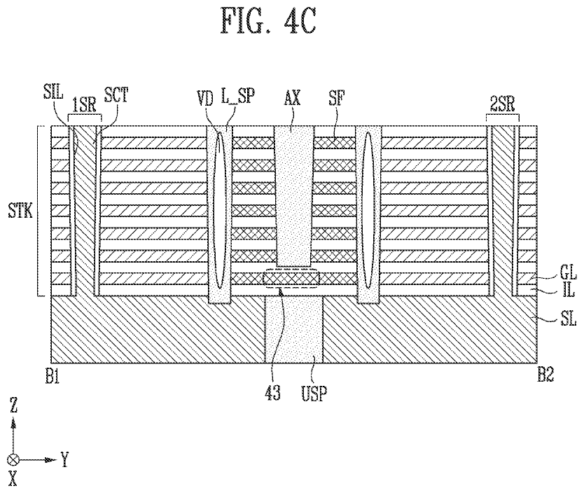

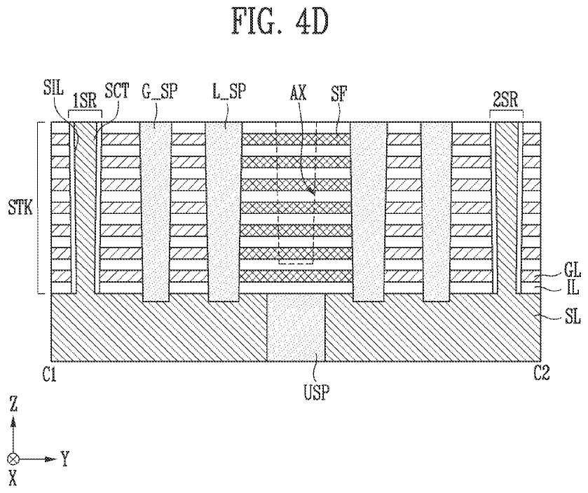

FIGS. 4A to 4D are diagrams illustrating a memory device including an auxiliary pattern according to an embodiment of the present disclosure.

FIG. 4A is a layout of the memory device, FIG. 4B is an enlarged layout of a portion 41 of FIG. 4A, FIG. 4C is a cross-sectional view of a structure of FIG. 4B taken in a direction B1-B2, and FIG. 4D is a cross section taken in a direction C1-C2.

For convenience of description, a description of structures overlapping those of FIGS. 3A to 3C is omitted.

Referring to FIG. 4A, auxiliary patterns AX may be disposed between the first supports L_SP facing each other. The auxiliary patterns AX may be disposed spaced apart from each other along the same direction X as the direction X in which the first supports L_SP extend between the first supports L_SP. The auxiliary patterns AX may be formed of the same material as the first supports L_SP. For example, the auxiliary patterns AX may be formed of an oxide material. The auxiliary patterns AX is more specifically described with reference to an enlarged view of the partial region 41 where the auxiliary patterns AX are included.

Referring to FIGS. 4A and 4B, the auxiliary patterns AX may be positioned between the first supports L_SP facing each other. When the protrusions PT are included in the first supports L_SP, the auxiliary patterns AX may be positioned between the protrusions PT included in different first supports L_SP and facing each other in a diagonal direction. Since the auxiliary patterns AX are positioned between the protrusions PT, a portion 42 of the void VD formed in the first supports L_SP may be removed during a subsequently performed heat treatment process. Removing the void VD means that the insulating material configuring the first supports L_SP fills the void VD. That is, the void VD may be removed while the insulating material configuring the first supports L_SP expands due to, in an embodiment, temperature of the heat treatment process. Although the void VD may also expand due to the temperature, since the auxiliary patterns AX are added, a pressure at which the insulating material of the first supports L_SP and the auxiliary patterns AX expand may be greater than a pressure at which the void VD expand. Each of the auxiliary patterns AX may have at least one layout among a rectangle, a square, an ellipse, and a circle. In an embodiment, the voids VD may be spaced from each other in a corresponding region between the auxiliary patterns as shown in FIG. 4B. For example, in an embodiment, the voids VD may be spaced from each other in a corresponding region with where the auxiliary patterns AX are spaced apart from each other, as shown in FIG. 4B. In an embodiment, each of the voids VD has a line shape extending in the first direction X as shown in FIG. 4B. In an embodiment, the first supports L_SP have a major axis corresponding to a length of the first direction X and a minor axis corresponding to a length of a second direction Y orthogonal to the first direction X, as shown in FIG. 4B. In an embodiment, a width of the minor axis of the first supports L_SP is narrower than a width of the auxiliary pattern AX. In an embodiment, the voids VD are spaced apart from each other in a region where the protrusions are positioned, as shown in FIG. 4B. In an embodiment, the auxiliary patterns AX are disposed between the protrusions PT that are symmetrical to each other, as shown in FIG. 4B.

Referring to FIGS. 4B to 4D, the insulating material directly filling the void VD of the first supports L_SP may be the insulating material configuring the first supports L_SP. However, since the insulating material included in the auxiliary patterns AX expands, the sacrificial layers SF or the insulating layers IL positioned between the auxiliary patterns AX and the first supports L_SP may apply a pressure in a direction of the protrusions PT by the auxiliary patterns AX. Therefore, a portion of the void VD may be filled with the insulating material of the first supports L_SP.

In a case of a cross section B1-B2 of FIG. 4C, since the auxiliary pattern AX is positioned between the first supports L_SP, the volume of the void VD formed in the first supports L_SP may be reduced during the subsequent heat treatment process. The auxiliary pattern AX may support the stack structure STK, but is formed to remove a portion of the void VD formed inside the first supports L_SP. Therefore, the auxiliary pattern AX might not reach a lowest end of the stack structure STK. For example, assuming that upper surfaces of the auxiliary pattern AX and the first supports L_SP are positioned on the same plane, a depth of the auxiliary pattern AX may be less than that of the first supports L_SP. Therefore, the first supports L_SP may pass through the stack structure STK to contact the source line SL, and the auxiliary pattern AX may pass through a portion of the stack structure STK to be spaced apart from the source line SL or the lower support USP. For example, the auxiliary pattern AX might not pass through a portion 43 of the sacrificial layers SF positioned below the stack structure STK. In an embodiment, the auxiliary pattern AX may be spaced apart from at least a lowermost sacrificial layer among the sacrificial layers as shown in FIG. 4C.

In a case of a cross section C1-C2 of FIG. 4D, the auxiliary patterns AX might not be included in the cross section C1-C2, but the auxiliary patterns AX may be positioned between the protrusions PT as shown in FIG. 4B. Therefore, during the subsequent heat treatment process, a portion of the void VD may be filled with the insulating material inside the auxiliary patterns AX and the first supports L_SP.

A method of manufacturing the memory device described with reference to FIGS. 4A to 4D is as follows.

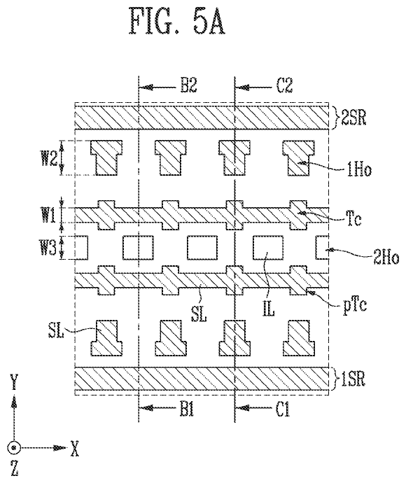

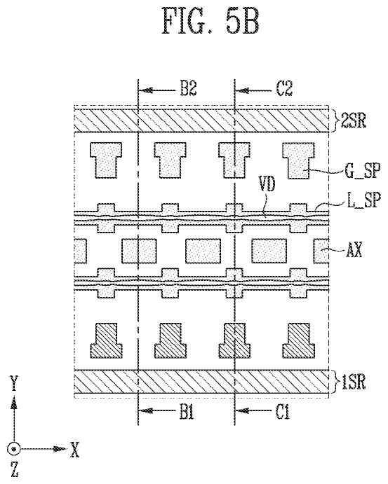

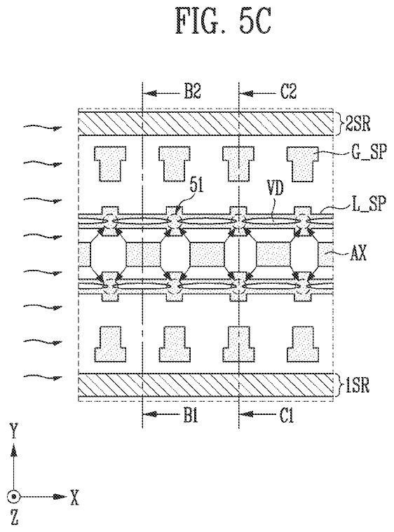

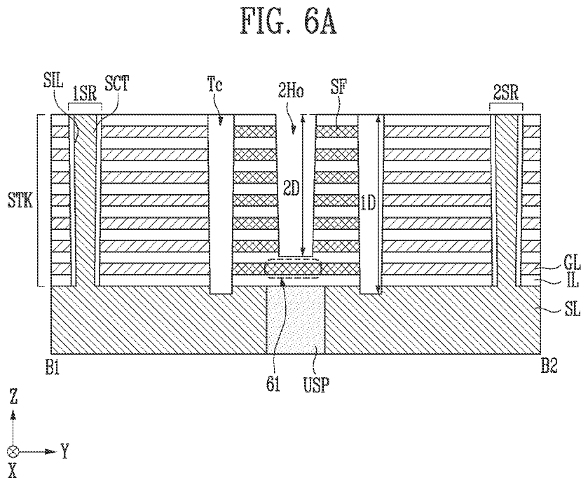

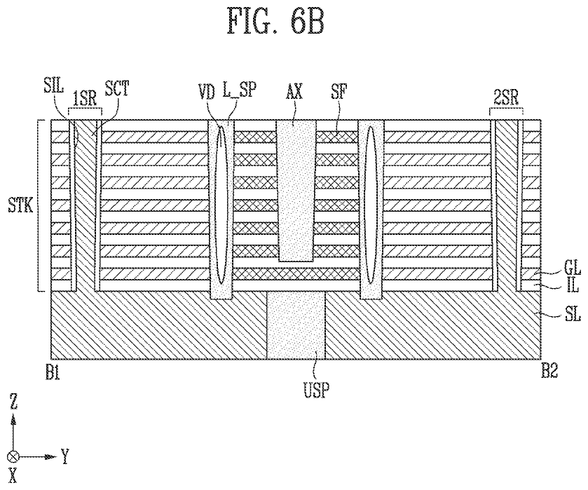

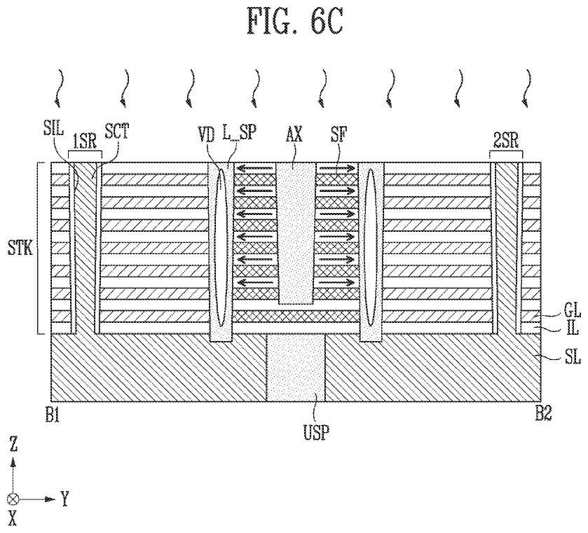

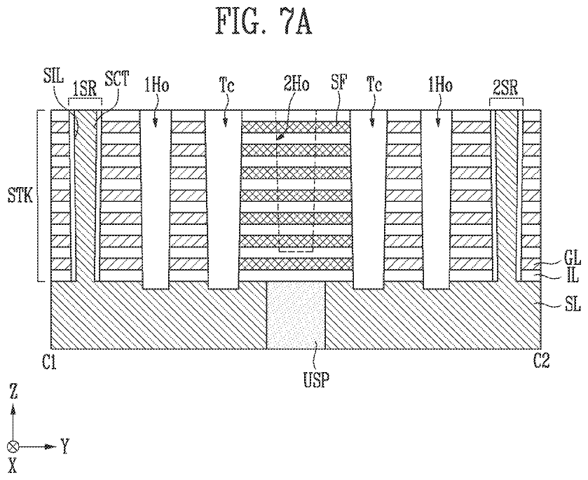

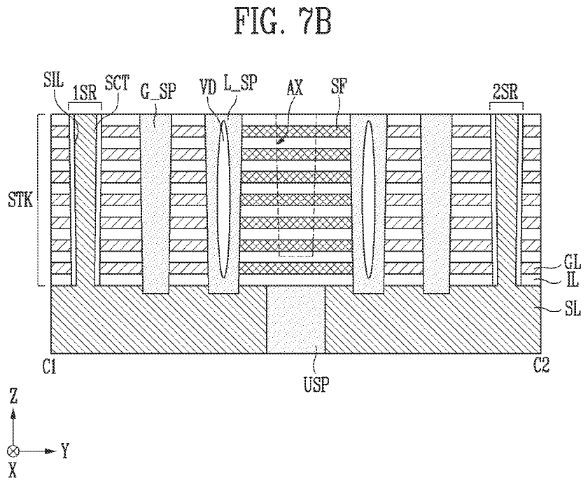

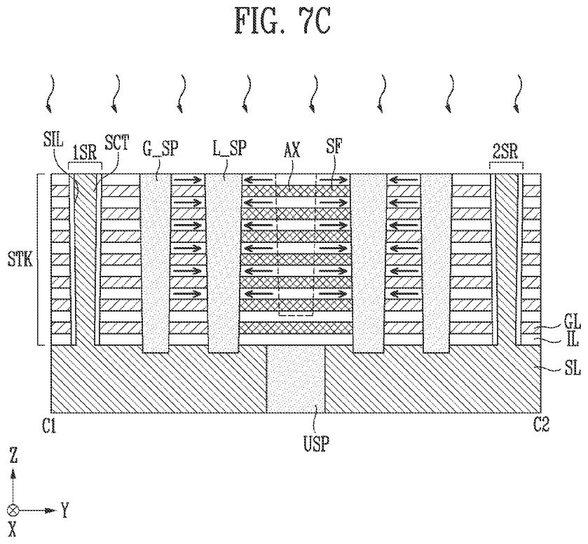

FIGS. 5A to 5C are layouts illustrating a method of manufacturing a memory device according to an embodiment of the present disclosure. FIGS. 6A to 6C are views illustrating a method of manufacturing a memory device according to an embodiment of the present disclosure, and are cross-sectional views of the memory device shown in FIGS. 5A to 5C taken in the direction B1-B2. FIGS. 7A to 7C are views illustrating a method of manufacturing a memory device according to an embodiment of the present disclosure, and are cross-sectional views of the memory device shown in FIGS. 5A to 5C taken in the direction C1-C2.

FIGS. 5A, 6A, and 7A are views corresponding to the same manufacturing step, FIGS. 5B, 6B, and 7B are views illustrating a next step of a manufacturing step described with reference to FIGS. 5A, 6A, and 7A, and FIGS. 5C, 6C, and 7C are views illustrating a next step of a manufacturing step described with reference to FIGS. 5B, 6B, and 7B.

Referring to FIGS. 5A, 6A, and 7A, the stack structure STK including the insulating layers IL, the gate lines GL, and the sacrificial layers SF may be formed on the source line SL. The lower support USP may be further formed in a portion of the region where the source line SL is formed. The lower support USP may be formed in a cylinder or line shape. The lower support USP may be formed to support the stack structure STK during the process of forming the source line SL. In an embodiment, the lower support USP may be positioned inside the source line SL and supporting the source line SL. The lower support USP may be formed of an insulating material. In an embodiment, the lower support USP may be positioned in a region lower than that of the auxiliary pattern AX as shown in FIG. 4C. The sacrificial layers SF may be positioned between the gate lines GL, the gate lines GL and the insulating layers IL may be alternately stacked, and the sacrificial layers SF and the insulating layers IL may also be alternately stacked. The First and second slit regions 1SR and 2SR may be defined at both ends of the stack structure STK. For example, when the first slit region 1SR is defined on one side of the stack structure STK, the second slit region 2SR may be defined on the other side of the stack structure STK. Since the sacrificial layers SF are positioned between the gate lines GL, the first and second slit regions 1SR and 2SR may be defined in a region passing through the gate lines GL and the insulating layers IL of the stack structure STK. The sidewall insulating layers SIL and the source contact SCT may be formed in each of the first and second slit regions 1SR and 2SR. The sidewall insulating layers SIL may be formed of an insulating material, and the source contact SCT may be formed of a conductive material that is in contact with the source line SL.

At etching process for forming trenches Tc and first holes 1Ho passing through the stack structure STK between the first and second slit regions 1SR and 2SR, and second holes 2Ho passing through a portion of the stack structure STK may be performed. The etching process for forming the trenches Tc and the first and second holes 1Ho and 2Ho may be simultaneously performed. The trenches Tc and the first holes 1Ho may pass through the stack structure STK to expose a portion of the source line SL. The second holes 2Ho may pass through a portion of the stack structure STK. The etching process for forming the trenches Tc and the first and second holes 1Ho and 2Ho may be performed by an anisotropic dry etching process. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Although the trenches Tc and the first and second holes 1Ho and 2Ho are simultaneously formed by the same etching process, depths may be different from each other according to the uppermost area of the trenches Tc and the first and second holes 1Ho and 2Ho. For example, the uppermost area of the second holes 2Ho may be less than that of the trenches Tc or the first holes 1Ho. For example, assuming that the trenches Tc have a first width W1 in the Y direction, the first holes 1Ho may have a second width W2 wider than the first width W1. The second holes 2Ho may have a third width W3 between the first and second widths W1 and W2.

During the etching process, since the etched area increases as the exposed area increases, an etching speed may also increase. Therefore, since an etching speed of the stack structure STL is lower than in the second holes 2Ho having the area less than that of the trenches Tc or the first holes 1Ho, even though the etching process is performed for the same time, when the trenches Tc or the first holds 1Ho have a first depth 1D, the second holes 2Ho may have a second depth 2D shallower than the first depth 1D. Accordingly, when the etching process is stopped when the source line SL is exposed through the trenches Tc and the first holes 1Ho, a portion 61 of the insulating layer IL or the sacrificial layer SF may be exposed through the second hole 2Ho.

The trenches Tc may be formed in a line shape extending along the X direction, and may include protrusion trenches pTc protruding in a direction in which the first and second slit regions 1SR and 2SR are positioned. The protrusion trenches pTc may be positioned at a regular distance along the X direction. The trenches Tc may be formed in a region of the stack structure STK adjacent to the gate lines GL and the sacrificial layers SF. Therefore, the insulating layers IL, the gate lines GL, and the sacrificial layers SF may be exposed through the trenches Tc. Since the first holes 1Ho are formed between the trenches Tc and the first or second slit region 1SR or 2SR, the insulating layers IL and the gate lines GL may be exposed through the first holes 1Ho. Since the second holes 2Ho are formed between the trenches Tc, the insulating layers IL and the sacrificial layers SF may be exposed through the second holes 2Ho.

Referring to FIGS. 5B, 6B, and 7B, an insulating material may be filled in the trenches Tc and the first and second holes 1Ho and 2Ho. For example, the insulating material may be an oxide layer. The insulating material filling the trenches Tc may become the first supports L_SP, and the insulating material filling the first holes 1Ho may become the second supports G_SP. The insulating material filling the second holes 2Ho may become the auxiliary patterns AX.

As shown in FIG. 5A, since the width of the trenches Tc is the narrowest among the trenches Tc and the first and second holes 1Ho and 2Ho, the void VD may be formed in the trenches Tc. For example, when the trenches Tc and the first and second holes 1Ho and 2Ho are filled with the insulating material, the void is not required to be formed in the trenches Tc and the first and second holes 1Ho and 2Ho. However, when the width of the trenches Tc is narrow compared to a step coverage of the insulating material, the void VD may be formed inside the trenches Tc. That is, when an upper portion of the trenches Tc is blocked by the insulating material before the inside of the trenches Tc is filled with the insulating material, the void VD may be formed inside the trenches Tc. The void VD may be formed in a line shape extending in the X direction along the trenches Tc. In a region where the protrusion trenches pTc among the trenches Tc are positioned, a width is relatively wide, and thus the width of the void VD may be relatively narrow.

Referring to FIGS. 5C, 6C, and 7C, a heat treatment process may be performed as a subsequent process. The heat treatment process may be performed at a high temperature to harden the insulating material configuring the first supports L_SP, the second supports G_SP, and the auxiliary patterns AX.

At this time, the insulating material configuring the first supports L_SP, the second supports G_SP, and the auxiliary patterns AX may expand by the high temperature. In particular, while the insulating material of the auxiliary patterns AX and the first supports L_SP expands, a portion of the void VD formed in the first supports L_SP may be filled with the insulating material. For example, among the first supports L_SP, since a volume of the insulating material is relatively large in a region 51 where the protrusions are positioned, the void VD may be removed in the region 51 where the protrusions are positioned. Accordingly, the void VD formed in the line shape in the first supports L_SP may be blocked in a partial region. When the volume of the voids VD is reduced, a phenomenon that the stack structure STK is bent by the voids VD in a subsequent process may be reduced, and thus, in an embodiment, yield of the manufacturing process of the memory device may be improved.

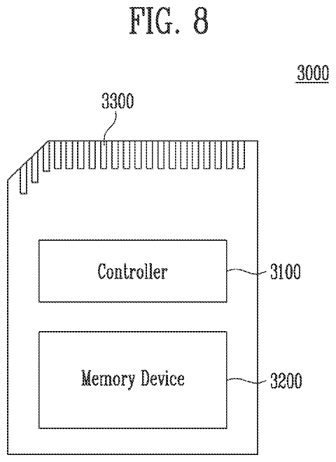

FIG. 8 is a diagram illustrating a memory card system to which a memory device of the present disclosure is applied.

Referring to FIG. 8, the memory card system 3000 includes a controller 3100, a memory device 3200, and a connector 3300.

The controller 3100 is connected to the memory device 3200. The controller 3100 is configured to access the memory device 3200. For example, the controller 3100 may be configured to control a program, read, or erase operation of the memory device 3200 or to control a background operation. The controller 3100 is configured to provide an interface between the memory device 3200 and a host. The controller 3100 is configured to drive firmware for controlling the memory device 3200. For example, the controller 3100 may include components such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 is configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include a plurality of memory cells, and may be configured identically to the memory device 100 shown in FIG. 1.

The controller 3100 and the memory device 3200 may be integrated into one semiconductor device to configure a memory card. For example, the controller 3100 and the memory device 3200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

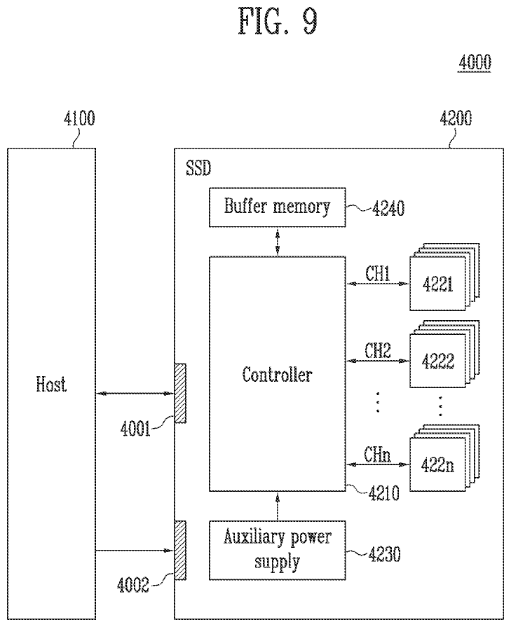

FIG. 9 is a diagram illustrating a solid state drive (SSD) system to which a memory device of the present disclosure is applied.

Referring to FIG. 9, the SSD system 4000 includes a host 4100 and an SSD 4200. The SSD 4200 exchanges a signal with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 is connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 operates as a buffer memory of the SSD 4200. For example, the buffer memory 4240 may temporarily store data received from the host 4100 or data received from the plurality of memory devices 4221 to 422n, or may store meta data (for example, a mapping table) of the memory devices 4221 to 422n. The buffer memory 4240 may include a volatile memory such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A memory device comprising:
source contacts passing through a stack structure stacked on a source line;
first supports passing through the stack structure between the source contacts;
second supports passing through the stack structure between the first supports and the source contacts; and
an auxiliary pattern passing through a portion of the stack structure between the first supports,
wherein the source contacts, and the first and second supports contact the source line, and
the auxiliary pattern is spaced apart from the source line.

2. The memory device of claim 1, wherein the source line and the source contacts comprise a conductive layer.

3. The memory device of claim 1, wherein the first and second supports and the auxiliary pattern comprise an insulating material.

4. The memory device of claim 1, further comprising:
sidewall insulating layers between the source contacts and the stack structure.

5. The memory device of claim 1, wherein the stack structure between the first supports includes insulating layers and sacrificial layers that are alternately stacked, and
the stack structure between the first supports and the source contacts includes the insulating layers and gate lines that are alternately stacked.

6. The memory device of claim 5, wherein the insulating layers comprise oxide layers,
the sacrificial layers comprise nitride layers, and
the gate lines comprise conductive layers.

7. The memory device of claim 5, wherein the first supports separate the sacrificial layers and the gate lines from each other.

8. The memory device of claim 5, wherein the auxiliary pattern is spaced apart from at least a lowermost sacrificial layer among the sacrificial layers.

9. The memory device of claim 1, further comprising:
a lower support positioned inside the source line and supporting the stack structure.

10. The memory device of claim 9, wherein the lower support comprises an insulating layer.

11. The memory device of claim 9, wherein the lower support is positioned in a region lower than that of the auxiliary pattern.

12. A memory device comprising:
first supports extending along a first direction and arranged parallel to each other;
auxiliary patterns spaced apart from each other along the first direction, the auxiliary patterns located between the first supports; and
voids spaced apart from each other along the first direction, the voids located inside the first supports.

13. The memory device of claim 12, wherein the first supports and the auxiliary patterns comprise insulating materials.

14. The memory device of claim 12, wherein the voids are spaced apart from each other in a corresponding region between the auxiliary patterns.

15. The memory device of claim 12, wherein each of the voids has a line shape extending in the first direction.

16. The memory device of claim 12, wherein the first supports have a major axis corresponding to a length of the first direction and a minor axis corresponding to a length of a second direction orthogonal to the first direction.

17. The memory device of claim 16, wherein a width of the minor axis of the first supports is narrower than a width of the auxiliary pattern.

18. The memory device of claim 12, further comprising:
protrusions protruding from the first supports and spaced apart from each other along the first direction.

19. The memory device of claim 18, wherein the voids are spaced apart from each other in a region where the protrusions are positioned.

20. The memory device of claim 18, wherein the auxiliary patterns are disposed between the protrusions that are symmetrical to each other.

21. The memory device of claim 12, wherein each of the auxiliary patterns has a layout of at least one of a rectangle, a square, an ellipse, and a circle.

22. A method of manufacturing a memory device, the method comprising:
forming first holes exposing a source line by passing through a stack structure positioned on the source line and spaced apart from each other in a first direction;
forming trenches exposing the source line by passing through the stack structure in a region spaced apart from the first holes in a second direction and having a line shape extending in the first direction;
forming second holes exposing a portion of the stack structure by passing through the portion of the stack structure between the trenches and spaced apart from each other in the first direction;
filling the first holes, the trenches, and the second holes with an insulating material; and
performing a heat treatment process for filling a portion of a void in the trenches.

23. The method of claim 22, wherein forming the first holes, forming the trenches, and forming the second holes are simultaneously performed by the same etching process.

24. The method of claim 23, wherein during the etching process, depths of the first holes, the trenches, and the second holes are different from each other due to a planar difference between the first holes, the trenches, and the second holes.
